(19) United States
(12) Patent Application Publication
(10) Pub. No.: US 2004/0195697 A1
(43) Pub. Date: Oct. 7, 2004

(54) Method of packaging circuit device and packaged device

(75) Inventors: Tan Hien Boon, Singapore (SG); Liu Hao, Singapore (SG); Park Soo Gill, Singapore (SG)

Correspondence Address: GREENBLUM & BERNSTEIN, P.L.C., 1950 ROLAND CLARKE PLACE, RESTON, VA, 20191, US

(73) Assignee: United Test & Assembly Center Ltd., Singapore (SG)

(21) Appl. No.: 10/403,040

(22) Filed: Apr. 1, 2003

(51) Int. Cl. H01L 23/48

(52) U.S. Cl. 257/767

(57) ABSTRACT

A method of packaging circuit devices in which a heat slug is inserted into an aperture in the substrate. A heat slug is therefore incorporated into the package without adding to the total size or weight of the package.

The present invention relates to the packaging of circuit devices, and is particularly applicable to plastic ball grid array (PBGA) packages.

A limiting factor on the performance and reliability of circuit devices is the dissipation of heat generated in the integrated circuit, IC. As the critical dimensions of circuit devices decrease, there are more logic units per unit area, and so the power generated by the device increases. Additionally, the size of chips is constantly increasing, further augmenting the power generated. The ambient temperature affects the performance of the device and heat dissipation is therefore crucial to the efficient operation of the circuit device.

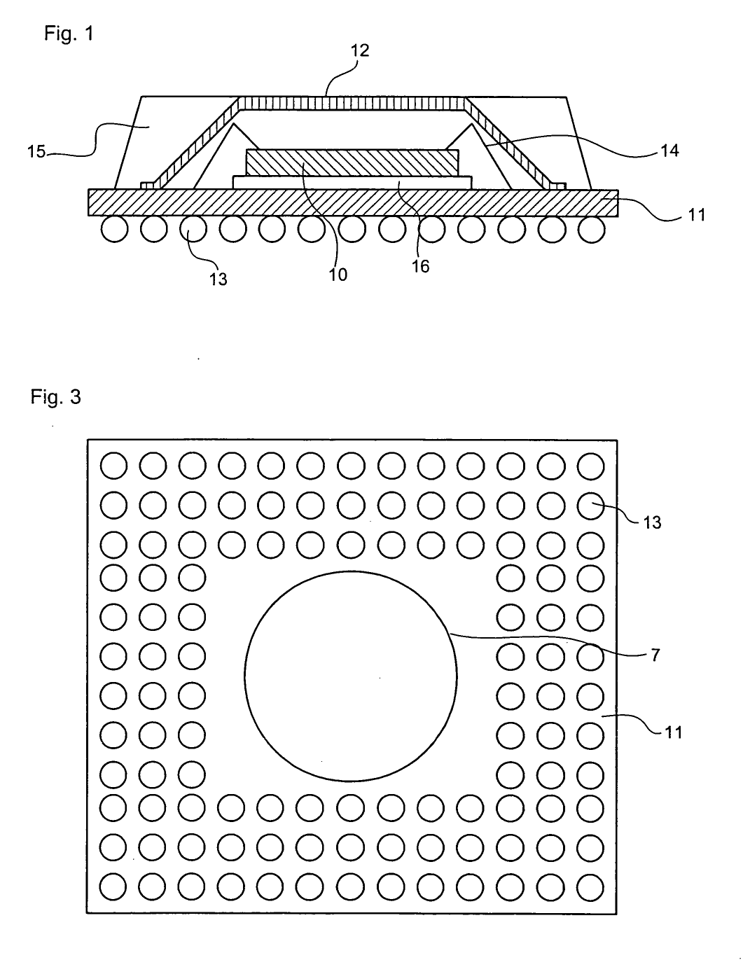

FIG. 1 of the accompanying drawings shows a conventional device packaging arrangement in which a chip 10 is adhered to a substrate 11 using die attach paste 16. Gold wires 14 provide electrical connections between the chip 10 and the substrate 11. The substrate 11 has solder balls 13 attached to the bottom side, which are used both for adhesion and as electrical connections. A heat slug 12 aids heat dissipation. The chip is then encapsulated with mould resin 15. Although this method can provide good heat dissipation, the thickness of the overall package is increased which is a significant disadvantage.

As an alternative to the heat slug a metal plane can be incorporated into the package. Although this method provides good conduction of heat, it greatly increases the weight and size of the package.

Accordingly, there is a requirement for a method of packaging circuit devices which efficiently dissipates heat without unnecessarily increasing the size of the packaging or total weight.

According to a first aspect of the invention there is provided a method of packaging a circuit device comprising the steps of:

providing a substrate having an aperture,

inserting a heat slug into said aperture; and

attaching said circuit device to said heat slug.

By placing the heat slug in an aperture of the substrate, the thickness of the package and the weight of the package are not increased The circuit device is then bonded to the substrate before encapsulation takes place. A further advantage of the present invention is the use of conventional bonding and encapsulation techniques. The cost of implementation of the invention will therefore be kept to a minimum. In a preferred embodiment of the invention the heat slug interlocks with the substrate which ensures that the heat slug remains rigidly in position. Additionally, or alternatively, the heat slug can be adhered to the substrate. The bottom of the heat slug and the substrate are preferably substantially planar.

Solder balls can be adhered to the bottom of the heat slug to conduct heat away from the heat slug. Alternatively the heat slug can protrude from the bottom of the substrate by the height of the collapsed solder balls, also aiding heat removal.

In a further preferred embodiment, the bottom of the circuit device is smaller than the area of the top of the heat slug. The whole of the bottom of the circuit device is therefore adhered to the heat slug. This results in the maximum possible heat dissipation. The surfaces of both the device and the heat slug should preferably be as smooth as possible to obtain the best thermal contact.

According to a further aspect of the invention there is provided a package device comprising:

a substrate having an aperture,

a heat slug fitted in said aperture;

a circuit device in thermal contact with said heat slug and in electrical contact with terminals on said substrate;

wherein the package is encapsulated.

According to a further aspect of the invention there is provided a plastic ball grid array substrate with an aperture for a heat slug.

The present invention will now be described by way of non-limiting examples with reference to the accompanying drawings, in which:

FIG. 1 schematically shows a package with a heat slug in a conventional arrangement,

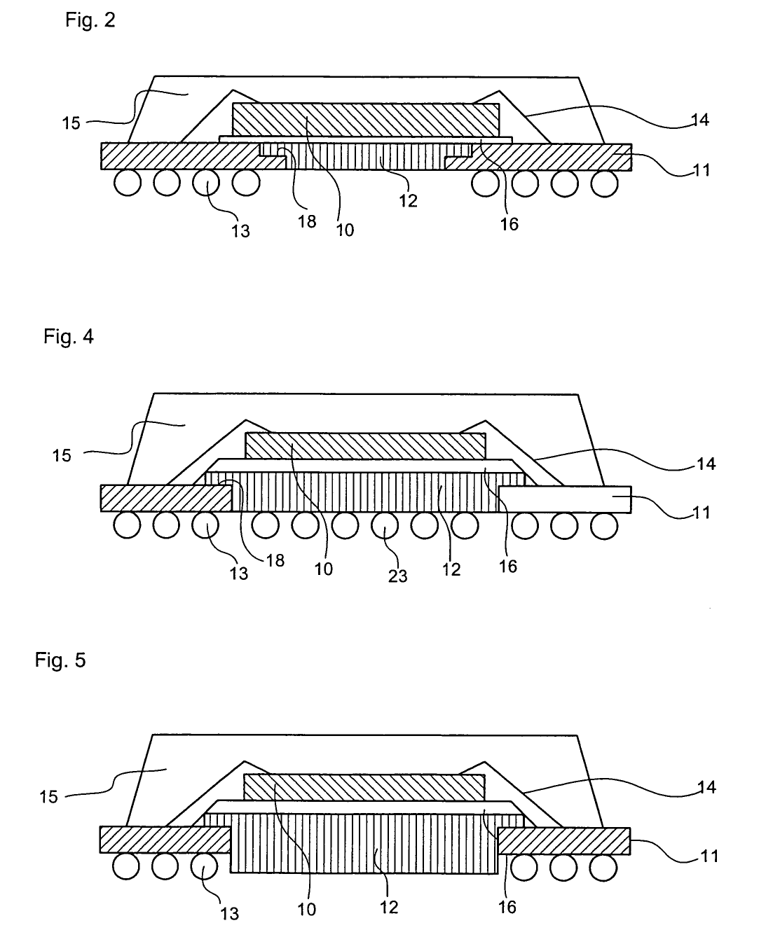

FIG. 2 shows a cross section of a package with a heat slug arranged according to the invention;

FIG. 3 is a plan view of a PBGA substrate according to the invention;

FIG. 4 schematically shows a package according to the invention with solder balls adhered to the bottom of the heat slug; and

FIG. 5 depicts a package according to the invention with a protruding heat slug.

In the figures, like parts are indicated by like reference numerals.

FIG. 2 shows a PBGA substrate 11 with an aperture 17 according to the invention. In FIG. 3, a heat slug 12 is shown inserted into the aperture 17 and in this embodiment, interlocking means 18 between the substrate 11 and the heat slug 12 ensure the heat slug remains in position. The bottom of the heat slug 12 and the bottom of the substrate 11 are substantially planar. A die 10 is adhered to the heat slug 12 by adhesive 16 and substrate 11, and then bonded to the substrate. The whole package is encapsulated with mould resin 15.

FIG. 4 differs from FIG. 2 in that the heat slug 12 is adhered to the substrate 11. Furthermore, the heat slug has a larger adhesion area than the die 10 as the whole side of the die is adhered to the heat slug, this provides the maximum possible heat dissipation. The heat slug shown in FIG. 4 has solder balls 23 adhered to the bottom to enhance the thermal flow away from the package. The solder balls shown here are substantially the same size as the substrate solder balls 13. They therefore conveniently adhere to the same surface.

FIG. 5 differs from FIG. 4 in that the heat slug 12 protrudes from the bottom of the substrate. Again, the height of the protrusion is the same as the depth of the collapsed solder balls 13 to ensure heat conduction.

Although the present invention has been described above with reference to exemplary embodiments, it will be appreciated that the invention is in no way limited to the embodiments described but rather the invention is defined by the scope of the following claims.

1. A method of packaging a circuit device comprising the steps of:
providing a substrate having an aperture,
inserting a heat slug into said aperture; and
attaching said circuit device to said heat slug.

2. A method of packaging circuit devices according to claim 1 further comprising the step of bonding the circuit device to the substrate.

3. A method of packaging circuit devices according to either claim 1 or claim 2 further comprising the step of encapsulating the volume above said circuit device.

4. A method of packaging a circuit device according to any one of the preceding claims wherein the heat slug interlocks with the substrate.

5. A method of packaging a circuit device according to any one of the preceding claims wherein the heat slug is adhered to the substrate.

6. A method of packaging circuit devices according to any one of the preceding claims wherein the bottom of the heat slug and the bottom of the substrate form a plane.

7. A method of packaging circuit devices according to any one of the preceding claims wherein the package is a plastic ball grid array.

8. A method of packaging circuit devices according to any one of the preceding claims wherein solder balls are attached to the bottom side of the heat slug.

9. A method of packaging circuit devices according to any one of claims 1 to 5 wherein the heat slug protrudes from the bottom of the substrate by the height of the solder balls when collapsed.

10. A method according to any one of the preceding claims, wherein the heat slug is a unitary body.

11. A plastic ball grid array substrate with an aperture for a heat slug.

12. A packaged device comprising:
a substrate having an aperture;
a heat slug fitted in said aperture;
a circuit device in thermal contact with said heat slug and in electrical contact with terminals on said substrate;
wherein the package is encapsulated.

13. A package device according to claim 12 wherein the heat slug interlocks with the aperture in the substrate.

14. A package according to either claim 12 or claim 13 wherein the substrate is a plastic ball grid array.
